(19) United States
(12) Patent Application Publication
(10) Pub. No.: US 2006/0121199 A1
(43) Pub. Date: Jun. 8, 2006

(54) Method of forming a metal thin film in a micro hole by ink-jet printing

(75) Inventors: Ming-Huan Yang, Hsinchu (TW); Chao-Kai Cheng, Hsinchu (TW); Chih-Jian Lin, Hsinchu (TW); Chih-Hsuan Chiu, Hsinchu (TW); Jane Chang, Hsinchu (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/201,127

(22) Filed: Aug. 11, 2005

(30) Foreign Application Priority Data
Dec. 8, 2004 (TW) 93138022

(51) Int. Cl. H05K 3/00; B05D 3/04

(52) U.S. Cl. 427/304; 427/97.7

(57) ABSTRACT

A method of forming micro holes metal membrane by inkjet printing spray micro droplets of a catalyst in the holes after the substrate surface is treated. The catalyst adsorbs and dries on the inner walls of the holes. After that, the surface properties of the substrate are changed so that the coating solution readily enters the holes and forms a membrane on their inner walls. This can avoid incomplete metal coating due to residual air in the holes and forming a disconnected circuit. Moreover, the adhesive force between the inner wall of the holes and the metal improves the situation of coated layer peeling. The method reduces the use of precious catalyst, the fabrication procedure, and the production of photo resist etching waste. Since it does not require expensive equipment and space for exposure, developing, laser drilling, the method lowers the production cost and satisfies the environmental protection requirements.

### BACKGROUND OF THE INVENTION

1. Field of Invention

The invention relates to a method for forming a metal thin membrane in a micro hole, and especially to a method for forming a metal thin membrane in a micro hole by Ink-Jet.

2. Related Art

Due to the rapid development in computing, communications, and general consuming electronic products, the production of printed circuit boards (PCB) has be evolved toward multiple layers, multiple functions, and high integration. Therefore, the PCB designs greatly adopt the idea of tiny micro holes, narrow pitches, and fine wires, which have caused great difficulties in PCB fabrication. However, there are some through holes with an aspect ratio over 5:1 or deeper blind holes in the multiple-layer plate, the normally used metal deposition method cannot satisfy the technical requirements of high quality and reliability for connecting holes.

To achieve the technical objects, aside from the control of micro holes electroplating current density in later steps and the use of additives, the most important is the chemical metal plating in early processes. This is because inappropriate electroless plating will seriously affect the quality of subsequent electroplating. In addition to the convection control of plating solution, an important step in the electroless plating process is the coating of catalyst in the micro holes. Currently, one method is to immerse a rough substrate with micro holes (through holes or blind holes) in a catalyst solution. The catalyst adsorbs on the inner walls of the micro holes. However, due to the use of deeper micro holes, air bubbles are likely to stay in the holes so that the catalyst cannot enter the micro holes. Therefore, phenomena of non-conduction or defects often occur after electroless plating. Inkjet printing (IJ) has long been discussed to be used in fabricating PCB. The earliest patent was proposed in 1979. The method is to inkjet print etching photo resist. In earlier 1990's, people also proposed the use of photo resist masks. However, these methods are not commercialized until recently. In the past couple of years, the inkjet printing technique and equipment have evolved from laboratory tests to the main power of printing technology. Many fundamental theories and jet head designs have been published. Therefore, the IJ can be widely used in printing, graphing, and related processes for the following three primary reasons. (1) This method can directly print materials at desired places. (2) This method utilizes a digitalized process. It has the ability to provide data writing and continuously changing the output without any interface. (3) This method accumulate a large amount of data in a non-impact way. These reasons enable the IJ technique to be applied to PCB and related processes. The simple and convenient printing design is more suitable for modern PCB fabrication.

Generally, the most common problem encountered in forming a metal membrane on a substrate by electroless plating is the inferior adhesiveness of the metal membrane. A conventional method for solving this problem is to employ physical polishing or chemical etching to increase the roughness of the substrate. However, this method is not applicable to all substrates. Rubner first proposed in 2000 to form several layers of self-assembling thin membranes on the substrate to print a polyelectrolyte. Afterwards, the substrate is immersed in a catalyst solution for the printed material to react with the catalyst, forming Pd-nanoparticles. Finally, nickel is deposited by electroless plating. The plating layers thus obtained have a better adhesiveness. Moreover, Yang Yang also proposed in 2001 a similar method to make vertical multi-layered circuit.

Modem processes tend to make the smaller micro holes and more complicated than before. The conventional manufacturing method will encounter problems of difficult fabrication and low yields. To solve these problems, we propose a novel idea. First, a cleansed substrate having micro holes is immersed in sequence in negative and positive polyelectrolytes. The inner walls of the micro holes in the PCB will be formed with self-assembly membranes (SAM's). Inkjet printing is then used to inject Pd-complex (catalyst) into the micro holes, filling them and reacting with the SAM's to form Pd-nanoparticles with the ability to catalyzing electrolessly plated copper. Finally, the substrate is placed in an electroless plating solution for plating. Since the droplets of the ink are smaller than the width of the micro holes, the catalyst can readily enter the micro holes and react with the SAM's. Moreover, since the surfaces of the SAM's are hydrophilic, no other surfactant or additive is required for the plating solution.

Currently, the conduction of microhole is achieved as follows. After the conduction channels among the layers are formed, dirt around and in the holes is cleansed by heavy polishing and high-pressure rinse. The gel debris on the wall of the hole are removed by a potassium permanganate solution. A Sn—Pd adhesive layer is attached on the cleared surface of the hole and reduced to Pd. Afterwards, the PCB is immersed in a chemical copper solution. With the catalyzing effect of Pd, the copper ions in the solution are reduced and deposited on the inner walls of the micro holes, forming a micro hole circuit. The copper layer inside the conduction holes is thickened by bath plating in CuSO₄ to an extent that is able to resist impacts in subsequent machining and uses. Due to the increases uses of micro holes, the conventional method of submerging in a catalyst often has the jamming problem caused by bubbles or atmospheric pressure. Such a problem is forbad the catalyst from entering the micro holes, resulting in poor electroless plating of the micro holes and conduction.

We list related patents up to now as follows.

U.S. Pat. No. 4,242,369 discloses a method of dispersing metal or alloy powders in a salt solution. The mixture is then used to fill the jet head. A pressure is imposed to squeeze out the material, which then forms metal on the substrate by electroless plating.

U.S. Pat. No. 4,459,320 discloses a method of fabricating micro holes. A material is coatedon a substrate with micro holes. Through steady stand, the material flows into the micro holes, followed by adding a substance that is able to lower the viscosity and increase the mobility of the material. After the micro holes are filled with the material, the surface residues are removed. Finally, the substrate is immersed in or coated with a solvent. After removing photo resist, the substrate can be exposed and developed accordingly.

U.S. Pat. No. 4,668,533 discloses an inkjet method for fabricating PCB's. It mainly applies a water-based material on the substrate to form a specific pattern. Electroless plating is employed to form metal on the specific pattern of the substrate.

U.S. Pat. No. 5,099,090 discloses a direct writer. It uses a tube device filled with electrically conducting material, which is squeezed onto the PCB and inside the micro holes.

U.S. Pat. No. 5,492,226 discloses a method using a solder mask. A solder paste is first reflowed so that it can readily flow through the PCB surface. It is then solidated thereon via a fine pitch solder mask.

U.S. Pat. No. 5,502,893 discloses a method of forming a plating layer in through holes of a metal plate. A metal plate having micro holes is first plated with a first layer of metal in the micro holes. A second layer of metal is then plated on the first metal layer. The second metal layer is then blackened, forming a non-conductive organic material thereon. Finally, a conductive circuit is formed on the non-conductive organic material.

U.S. Pat. No. 6,083,834 uses zinc salt as the catalyst. A test plate is immersed in an aqueous solution containing zinc oxide, potassium hydroxide, sodium hydroxide, and sodium hydrogencarbonate. The metal zinc is reduced on the surface of the substrate, followed by coating other metal layers, such as Ag, Cu, and Al.

U.S. Pat. No. 6,518,168 employs a stamp to form SAM's or sol-gel on a substrate. By chemical vapor deposition (CVD), a catalyst, organic or metal material is formed on the substrate. The substrate may have the structure of grooves or holes.

Germany Pat. No. 3806884 discloses a method of placing a test plate with micro holes in a solution containing conductive polymers. The test plate is then immersed in an acid solution containing oxidants to perform a polymerization reaction to form conductive polymers. The micro holes are then deposited with metal by electroplating or electroless plating.

Germany Pat. No. 4446881 discloses a method of using a photo mask to coat a metal layer in the micro holes. A layer of nickel is then grown thereon by electroless plating. The metal is then deposited to the required thickness by electroplating.

Japanese Patent Laid-Open No. 4305932 discloses a method with the aid of laser and photo mask. The laser is employed to heat up the substrate, so that the plating solution in the micro holes uncovered by the photo mask undergoes thermal decomposed. Afterwards, the metal is reduced in the micro holes. In addition, this method can be used in preparing metal wired circuits.

### SUMMARY OF THE INVENTION

In light of the foregoing issues, an object of the invention is to provide an inkjet printing method to form a metal membrane in micro holes. This method changes the properties of the substrate surface to hydrophilic, so that the plating solution can readily enter the micro holes for electroless plating.

To achieve the above object, the disclosed method includes the following steps. First, a substrate having micro holes is provided. Its surface is then treated to become hydrophilic. Porous elements are formed on the back surface of the substrate. A catalyst is then sprayed inside the micro holes by micro droplet coating. The catalyst adsorbs and dries on the inner walls of the micro holes. That is, the substrate with a hydrophilic surface enables the catalyst to effectively adsorb onto the inner walls of the micro holes. After the catalyst dries, it adheres on the inner walls. Since the diameters of the catalyst droplets are smaller than the diameter of the micro holes, no jam will be caused by bubbles or atmospheric pressure when the catalyst is injected into the micro holes. Therefore, the invention can greatly increase the reliability of the electroless plating of micro holes. Afterwards, the porous elements are departed from the back surface of the substrate. Finally, a metal membrane is formed on the inner walls of the micro holes by placing the substrate in a plating solution. The hydrophilic surface of the substrate enables the plating solution to enter the micro holes for electroless plating.

Moreover, the invention can prevent air from staying in the micro holes and causing disconnected circuits as a result of incomplete electroless metal plating. The good adhering force between the inner walls of the micro holes and the metal can prevent the plating layer (metal membrane) from peeling off. The inkjet method can reduce the use of precious metal salts (catalysts), fabricating procedure, and the production of wastes from photo resist etching. Since it does not require expensive equipment and large space for exposure, developing and laser drilling, the invention can lower the production cost and satisfy the environmental protection requirements.

### BRIEF DESCRIPTION OF THE DRAWINGS

The invention will become more fully understood from the detailed description given hereinbelow illustration only, and thus are not limitative of the present invention, and wherein:

FIGS. 1A to 1G are schematic views of applying the invention to micro holes on a substrate;

FIGS. 2A to 2E are schematic views of porous materials;

FIGS. 3A to 3E are schematic views of applying the invention to blind holes on a substrate;

FIG. 4 is a flowchart of the disclosed method applying to micro holes on a substrate;

FIGS. 5A and 5B are detailed flowcharts of step 102 in FIG. 4;

FIG. 6 is a flowchart of the disclosed method applying to blind holes on a substrate; and

FIGS. 7A and 7B are detailed flowcharts of step 202 in FIG. 6.

### DETAILED DESCRIPTION OF THE INVENTION

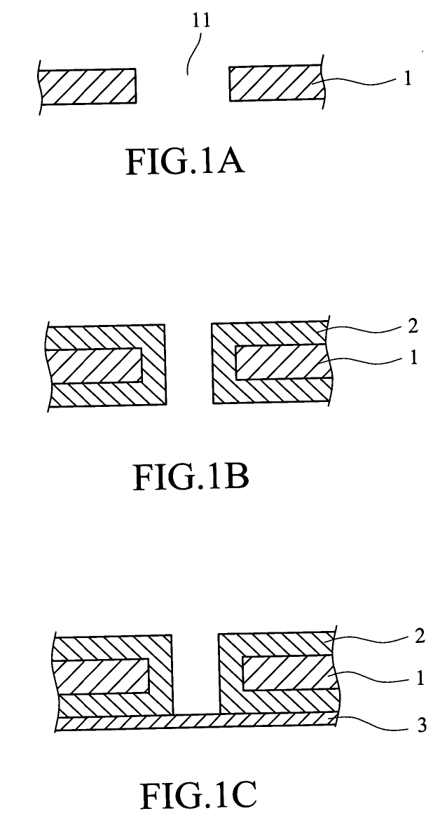

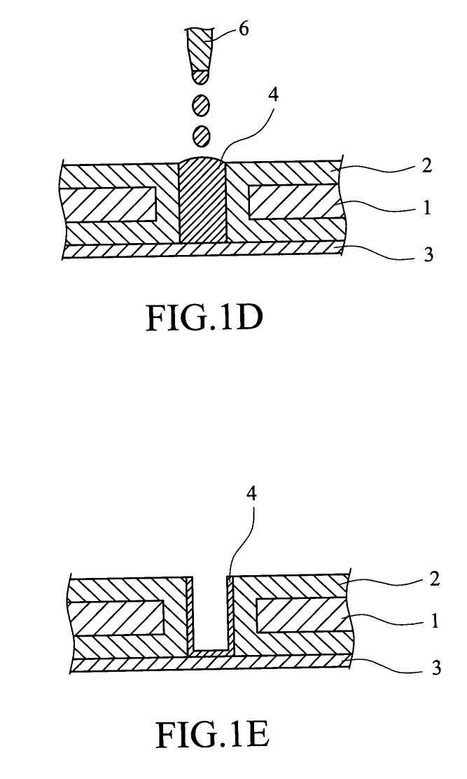

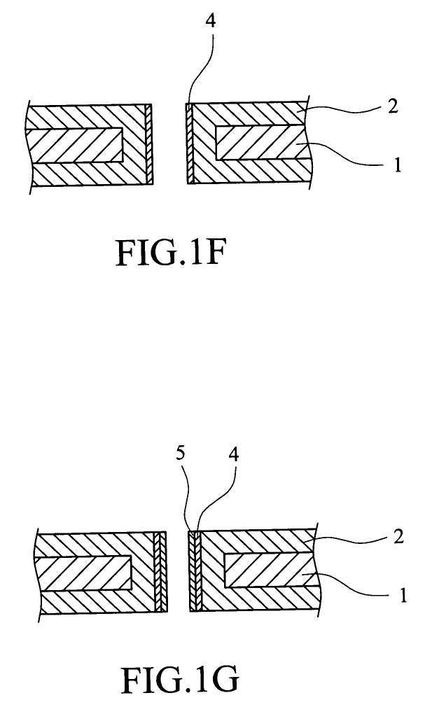

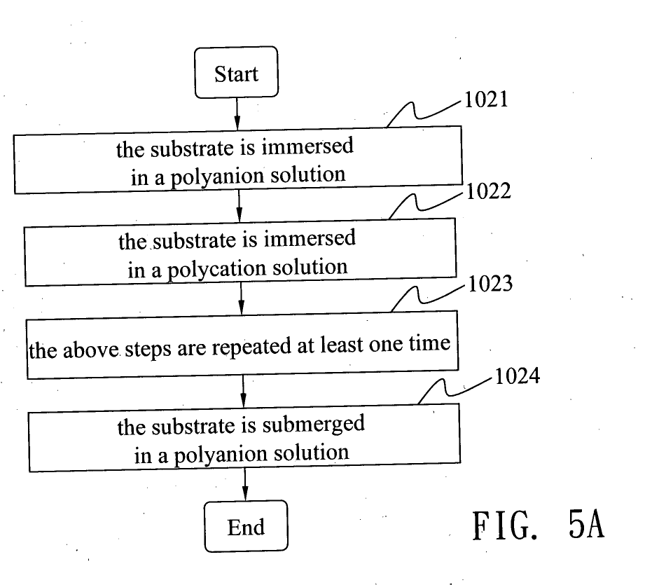

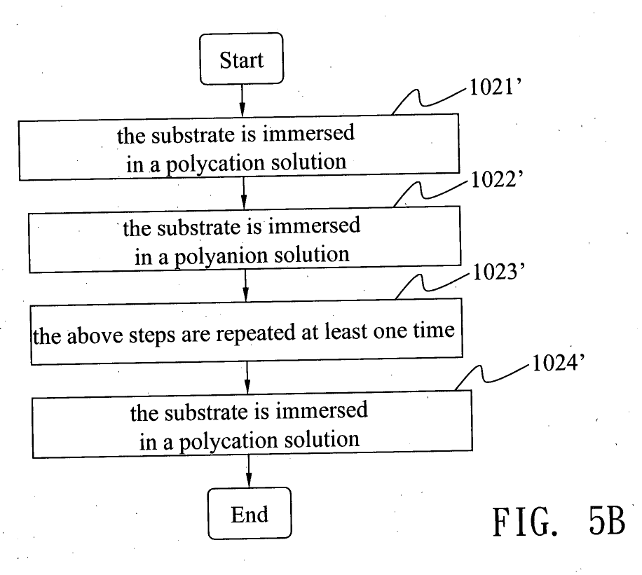

The application of the invention to a substrate with micro holes is schematically shown in FIGS. 1A to 1G. FIG. 4 is a flowchart of the disclosed method. FIGS. 5A and 5B illustrate the detailed procedure of step 102 in FIG. 4. We describe the steps of the method of forming a metal film in the micro holes using inkjet printing according to the invention as follows.

First, a substrate 1 having micro holes 11 is provided (step 101), as shown in FIG. 1A. The material of the substrate 1 is selected from glass, PET, FR-4, flexible FR-4, and polyamide.

The surface of the substrate 1 is treated (step 102), as shown in FIG. 1B. The surface treatment includes plasma treatment and nature modification. For the nature modification, a self-assembly membrane (SAM) 2 can be formed on the substrate, including the following steps:

The substrate 1 is first immersed in a polyanion solution (step 1021). The polyanion is selected from polyacrylic acid (PAA), PMA, and PTAA.

The substrate 1 is then immersed in a polycation solution (step 1022). The polycation is selected from polyallylamine hydrochloride (PAH), PVI⁺, PVP⁺, and PAN. Generally speaking, a SAM 2 can be formed on the surface of the substrate after it is immersed in two oppositely charged polyelectrolytes.

The above steps are repeated at least one time (step 1023). To effectively modify the nature of the surface of the substrate 1, the step can be repeated to stack multiple PAH/PAA bilayers.

The substrate 1 is then immersed in a polyanion solution (step 1024). This step forms multiple layers of nano-grade SAM interfaces 2.

Of course, the nature modification can be modified to be the following steps: first, the substrate 1 is immersed in a polycation solution (step 1021′) and then in a polyanion solution (step 1022′). The above steps are repeated at least one time (step 1023′). Finally, the substrate 1 is immersed in a polycation solution. (step 1024′).

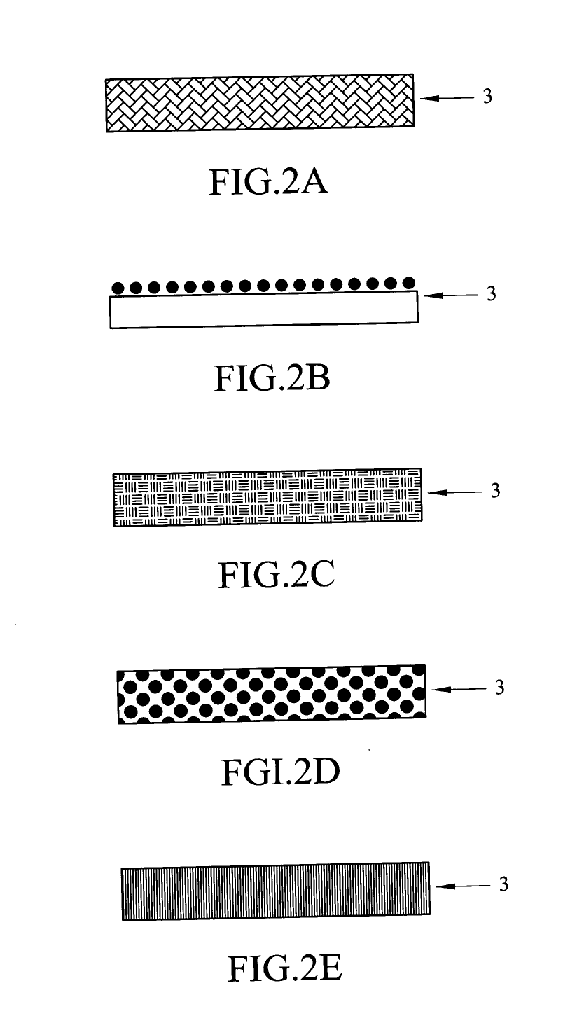

A porous material 3 is provided on the back surface of the substrate 1 (step 103), as shown in FIG. 1C. The porous material 3 is selected from one of (1) fibers, (2) surface-treated materials with slightly rough surfaces, (3) materials with multiple layers of membranes attached together and with small gaps, (4) a porous material in the mixture of a homogeneous material and small granules, and (5) a porous material with embossed granules. (Please refer to the schematic views of porous materials shown in FIGS. 2A to 2E.) The porous material is attached on the back of the substrate 1 by an adhesive agent. Alternatively, the porous material and the substrate 1 are adsorbed tightly together by a vacuum source. This can avoid the catalyst 4 from flowing out of the micro holes 11 as it is dripped into the micro holes 11.

The catalyst 4 (e.g. Pd-complex) is inkjet sprayed into the micro holes 11. The catalyst 4 then adsorbs and dries on the surfaces of the micro holes 11 (step 104), as shown in FIGS. 1D and 1E. Simply because of the formation of the SAM 2, the catalyst 4 sprayed by the hole 6 can be effectively applied onto the surfaces of the micro holes 11 and adhere thereon after it dries, forming Pd-nanoparticles. Since the diameters of the catalyst 4 droplets (30 μm) are generally smaller than the diameter of the micro holes 11, no bubble jams or atmospheric pressure resistance would occur when the catalyst 4 is injected into the micro holes 11. This can greatly increase the reliability of the electroless plating on the micro holes 11. The catalyst 4 is selected from Na₂PdCl₄ or Pd(NH₃)₄Cl₂ solution. When the catalyst 4 is a Na₂PdCl₄ solution, the nature modification has the steps 1021 to 1024. When the catalyst 4 is a Pd(NH₃)₄Cl₂ solution, then it takes the steps 1021′ to 1024′.

The porous material 3 is then departed from the back of the substrate 1 (step 105), as shown in FIG. 1F.

Finally, in plating solution a metal membrane 5 is formed on the surfaces of the micro holes 11 (step 106). The material of the metal membrane 5 is copper. This is shown in FIG. 1G. Of course, since the surface of substrate 1 is treated to become hydrophilic, the plating solution can readily enter the micro holes 11 for electroless plating. Moreover, the invention can prevent air from staying inside the micro holes and causing broken circuits due to incomplete electroless plating. A good adhesive force exists between the inner walls of the micro holes and the metal. It can prevent the plating layer (metal membrane) from peeling off. The inkjet method can reduce the use of precious metal salts (catalyst), the fabrication procedure, and the production of photo resist etching waste. Since it does not require expensive equipment and space for exposure, developing, laser drilling, the invention can lower the production cost and satisfy the environmental protection requirements.

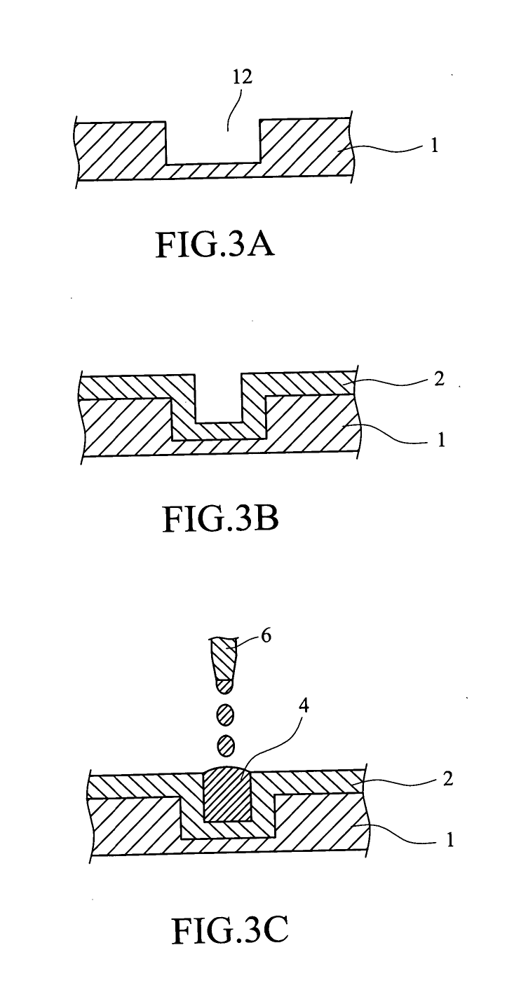

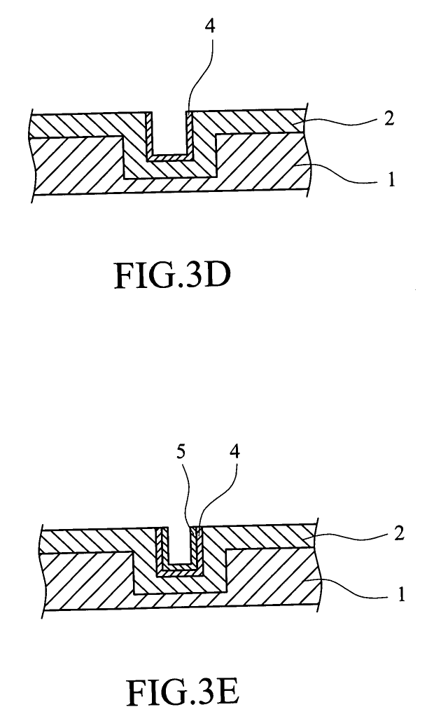

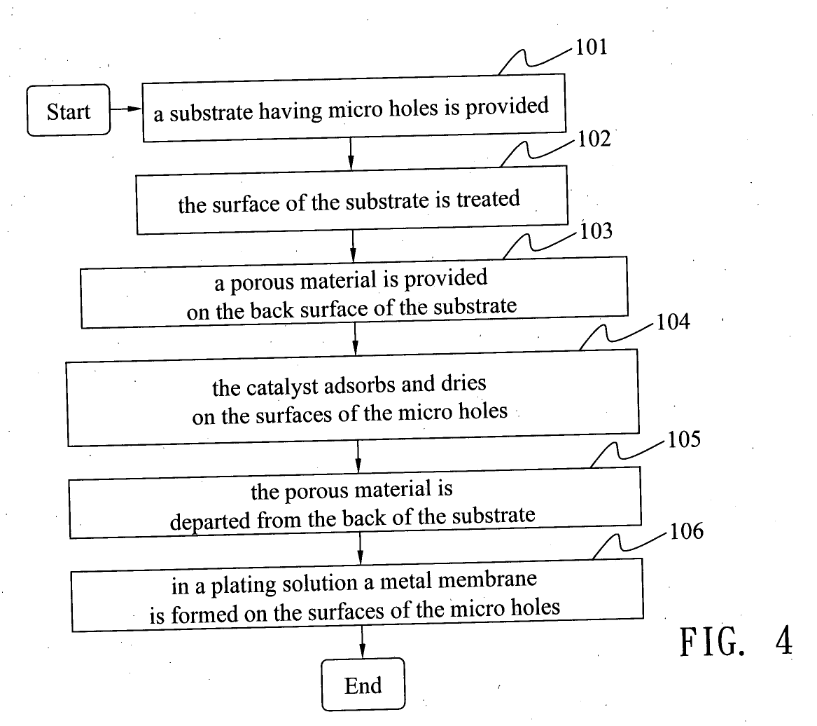

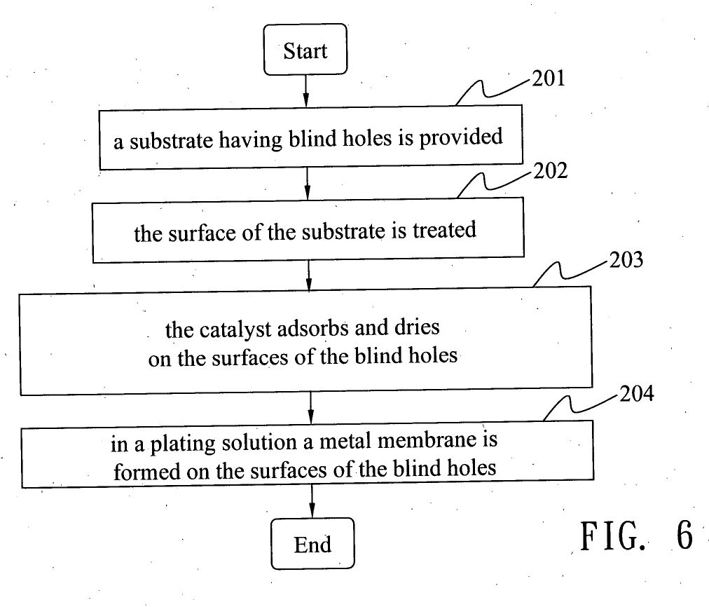

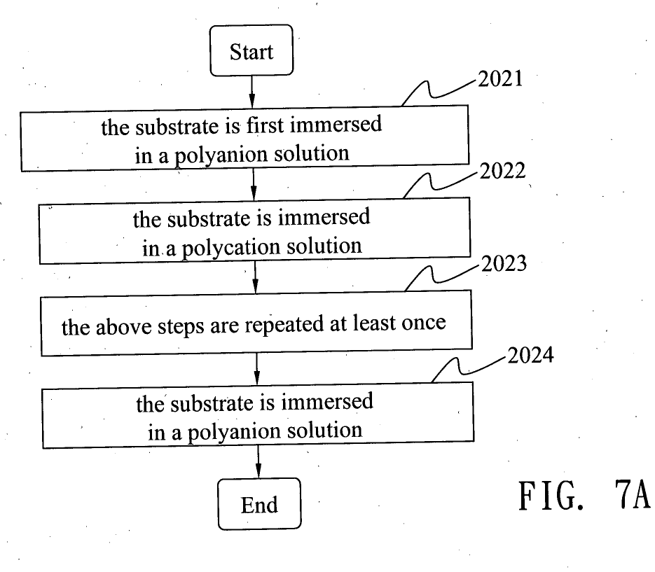

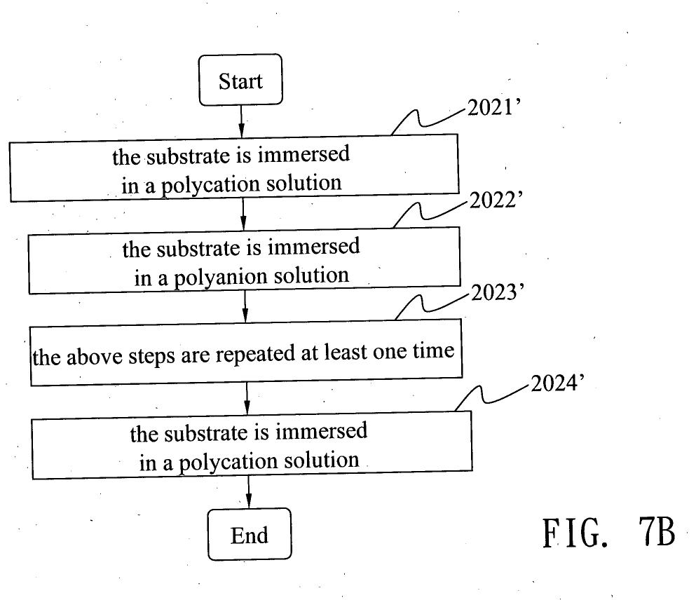

FIGS. 3A to 3E illustrate the application of the invention to blind holes on a substrate. FIG. 6 shows the flowchart of the procedure. FIGS. 7A and 7B show detailed procedures of step 202 in FIG. 6. The disclosed method of forming a metal film in blind holes by inkjet printing includes the following steps.

First, a substrate 1 having blind holes 12 is provided (step 201), as shown in FIG. 3A. The material of the substrate 1 is selected from glass, PET, FR-4, flexible FR-4, and polyamide.

The surface of the substrate 1 is treated (step 202), as shown in FIG. 3B. The surface treatment includes plasma treatment and nature modification. For the nature modification, a self-assembly membrane (SAM) 2 can be formed on the substrate, including the following steps:

The substrate 1 is first immersed in a polyanion solution (step 2021). The polyanion is selected from PAA, PMA, and PTAA.

The substrate 1 is then immersed in a polycation solution (step 2022). The polycation is selected from PAH, PVI⁺, PVP⁺, and PAN.

The above steps are repeated at least once (step 2023). The substrate 1 is then immersed in a polyanion solution. (step 2024).

Of course, the nature modification can be modified to be the following steps: first, the substrate 1 is immersed in a polycation solution (step 2021′) and then in a polyanion solution. (step 2022′). The above steps are repeated at least one time (step 2023′). Finally, the substrate 1 is immersed in a polycation solution. (step 2024′).

The catalyst 4 (e.g. Pd-complex) is inkjet sprayed into the blind holes 12. The catalyst 4 then adsorbs and dries on the surfaces of the blind holes 11 (step 203), as shown in FIGS. 3C and 3D. Simply because of the formation of the SAM 2, the catalyst 4 sprayed by the hole 6 can be effectively applied onto the surfaces of the blind holes 12 and adhere thereon after it dries, forming Pd-nanoparticles. Since the diameters of the catalyst 4 droplets (30 μm) are generally smaller than the diameter of the blind holes 12, no bubble jams or atmospheric pressure resistance would occur when the catalyst 4 is injected into the blind holes 12. This can greatly increase the reliability of the electroless plating on the blind holes 12. The catalyst 4 is selected from Na₂PdCl₄ or Pd(NH₃)₄Cl₂ solution. When the catalyst 4 is a Na₂PdCl₄ solution, the nature modification has the steps 2021 to 2024. When the catalyst 4 is a Pd(NH₃)₄Cl₂ solution, then it takes the steps 2021′ to 2024′.

Finally, in plating solution a metal membrane 5 is formed on the surfaces of the blind holes 12 (step 204). The material of the metal membrane 5 is copper. This is shown in FIG. 3E. Of course, since the surface of substrate 1 is treated to become hydrophilic, the plating solution can readily enter the blind holes 12 for electroless plating. Moreover, the invention can prevent air from staying inside the micro holes and causing broken circuits due to incomplete electroless plating. A good adhesive force exists between the inner walls of the micro holes and the metal. It can prevent the plating layer (metal membrane) from peeling off. The inkjet method can reduce the use of precious metal salts (catalyst), the fabrication procedure, and the production of photo resist etching waste. Since it does not require expensive equipment and space for exposure, developing, laser drilling, the invention can lower the production cost and satisfy the environmental protection requirements.

Certain variations would be apparent to those skilled in the art, which variations are considered within the spirit and scope of the claimed invention.

What is claimed is:

1. An inkjet printing method for forming a metal membrane in micro holes, comprising the steps of:
providing a substrate having a micro hole;
performing a surface treatment on the substrate;
providing a porous material on the back of the substrate;
applying a catalyst by micro droplet inkjet in the micro hole and letting the catalyst adsorb and dry on the inner wall of the micro hole;
peeling off the porous material from the back of the substrate; and
forming a metal membrane on the inner wall of the micro hole in a plating solution.

2. The method of claim 1, wherein the catalyst is a Na₂PdCl₄ solution and in the step of performing a surface treatment on the substrate, the surface treatment is nature modification to form a self-assembly membrane (SAM) so that the catalyst effectively adsorbs and dries on the inner wall of the micro hole, and the method further comprises the steps of:
(A) immersing the substrate in a polyanion solution;
(B) immersing the substrate in a polycation solution;
(C) repeating the steps (A) and (B) at least once; and
(D) immersing the substrate in the polyanion solution.

3. The method of claim 2, wherein the polyanion is selected from the group comprising polyacrylic acid (PAA), PMA, and PTAA.

4. The method of claim 2, wherein the positive-ion polycation is selected from the group comprising polyallylamine hydrochloride (PAH), PVI⁺, PVP⁺, and PAN.

5. The method of claim 2, wherein the material of the substrate is selected from the group comprising glass, PET, FR-4, flexible FR-4, and polyamide.

6. The method of claim 1, wherein the catalyst is a Pd(NH₃)₄Cl₂ solution and in the step of performing a surface treatment on the substrate, the surface treatment is nature modification to form a self-assembly membrane (SAM) so that the catalyst effectively adsorbs and dries on the inner wall of the micro hole, and the method further comprises the steps of:
(A) immersing the substrate in a polycation solution;
(B) immersing the substrate in a polyanion solution;
(C) repeating the steps (A) and (B) at least once; and
(D) immersing the substrate in the polycation solution.

7. The method of claim 6, wherein the polyanion is selected from the group comprising polyacrylic acid (PAA), PMA, and PTAA.

8. The method of claim 6, wherein the polycation is selected from the group comprising polyallylamine hydrochloride (PAH), PVI⁺, PVP⁺, and PAN.

9. The method of claim 6, wherein the material of the substrate is selected from the group comprising glass, PET, FR-4, flexible FR-4, and polyamide.

10. The method of claim 1, wherein the material of the metal membrane is copper.

11. The method of claim 1, wherein the porous material is selected from one of the group comprising (1) fibers, (2) surface-treated materials with slightly coarsened surfaces, (3) materials with multiple layers of membrane attached together and with small gaps, (4) a porous material in the mixture of a homogeneous material and small granules, and (5) a porous material with embossed granules.

12. The method of claim 1, wherein the surface treatment is plasma treatment.

13. The method of claim 1, wherein in the step of providing a porous material on the back of the substrate the porous material is adhered on the back of the substrate by an adhesive agent.

14. The method of claim 1, wherein in the step of providing a porous material on the back of the substrate the porous material and the substrate are simultaneously adsorbed tightly by a vacuum source.

15. An inkjet printing method for forming a metal membrane in blind holes, comprising the steps of:
providing a substrate having a blind hole;
performing a surface treatment on the substrate;
applying a catalyst by micro droplet inkjet in the blind hole and letting the catalyst adsorb and dry on the inner wall of the blind hole; and
forming a metal membrane on the inner wall of the blind hole in a plating solution.

16. The method of claim 15, wherein the catalyst is a Na₂PdCl₄ solution and in the step of performing a surface treatment on the substrate, the surface treatment is nature modification to form a self-assembly membrane (SAM) so that the catalyst effectively adsorbs and dries on the inner wall of the micro hole, and the method further comprises the steps of:
(A) immersing the substrate in a polyanion solution;
(B) immersing the substrate in a polycation solution;
(C) repeating steps (A) and (B) at least once; and
(D) immersing the substrate in the polyanion solution.

17. The method of claim 16, wherein the polyanion is selected from the group comprising polyacrylic acid (PAA), PMA, and PTAA.

18. The method of claim 16, wherein the polycation is selected from the group comprising polyallylamine hydrochloride (PAH), PVI⁺, PVP⁺, and PAN.

19. The method of claim 16, wherein the material of the substrate is selected from the group comprising glass, PET, FR-4, flexible FR-4, and polyamide.

20. The method of claim 15, wherein the catalyst is a Pd(NH₃)₄Cl₂ solution and in the step of performing a surface treatment on the substrate, the surface treatment is nature modification to form a self-assembly membrane (SAM) so that the catalyst effectively adsorbs and dries on the inner wall of the micro hole, and the method further comprises the steps of:
(A) immersing the substrate in a polycation solution;
(B) immersing the substrate in a polyanion solution;
(C) repeating the steps (A) and (B) at least once; and
(D) immersing the substrate in the polycation solution.

21. The method of claim 20, wherein the polyanion is selected from the group comprising polyacrylic acid (PAA), PMA, and PTAA.

22. The method of claim 20, wherein the polycation is selected from the group comprising polyallylamine hydrochloride (PAH), PVI⁺, PVP⁺, and PAN.

23. The method of claim 20, wherein the material of the substrate is selected from the group comprising glass, PET, FR-4, flexible FR-4, and polyamide.

24. The method of claim 15, wherein the material of the metal membrane is copper.

25. The method of claim 15, wherein the surface treatment is plasma treatment.
